(19) United States
(12) Patent Application Publication
(10) Pub. No.: US 2019/0378690 A1
(43) Pub. Date: Dec. 12, 2019

(54) ION IMPLANTATION APPARATUS AND ION IMPLANTATION METHOD

(71) Applicant: ELECTRONICS AND TELECOMMUNICATIONS RESEARCH INSTITUTE, Daejeon (KR)

(72) Inventors: Moon Youn JUNG, Daejeon (KR); Won Bae CHO, Daejeon (KR)

(21) Appl. No.: 16/435,361

(22) Filed: Jun. 7, 2019

(30) Foreign Application Priority Data
Jun. 8, 2018 (KR) 10-2018-0066334
May 22, 2019 (KR) 10-2019-0059977

(51) Int. Cl. H01J 37/317; H01J 37/08; H01J 37/20

(52) U.S. Cl. CPC H01J 37/3171; H01J 37/08; H01J 2237/0807; H01J 2237/20214; H01J 37/20

(57) ABSTRACT

Provided is an ion implantation method. An ion implantation method according to an embodiment of the inventive concept may include providing a host material and a target into a chamber, the target comprising a first material; irradiating the target with a laser to generate an ion beam; and irradiating the host material with the ion beam to dope the host material with the first material, wherein while the host material is irradiated with the ion beam, the host material is rotated.

### CROSS-REFERENCE TO RELATED APPLICATIONS

This U.S. non-provisional patent application claims priority under 35 U.S.C. § 119 of Korean Patent Application No. 10-2018-0066334, filed on Jun. 8, 2018, and Korean Patent Application No. 10-2019-0059977, filed on May 22, 2019, the entire contents of which are hereby incorporated by reference.

### BACKGROUND

The present disclosure herein relates to an ion implantation apparatus and ion implantation method, and more particularly, to an ion implantation apparatus including a laser device and an ion implantation method using the same.

Gain materials of solid laser devices may be prepared by doping ions on host materials. The laser devices may cause lasers having different wavelengths to oscillate according to the types of host materials of gain materials and dopants. For example, in a laser device using FeZnSe as a gain material, Fe²⁺ ions may cause wavelengths within a range of about 3.5-4.5 μm to oscillate when having a concentration of about 10¹⁷-10¹⁸ ions per 1 cm³.

A methods for preparing a gain material of a laser device may include, for example, providing a reaction furnace with Fe powder and ZnSe crystals and maintaining the reaction furnace at about 800-1200° C. for about 100-150 hours. The method for preparing the abovementioned gain material may be applied in the same manner to a method for implementing the color of an artificial jewel. As ion doping methods are used in various industrial fields, study on an ion doping method that may be performed in a short time with a low cost are being actively carried out.

### SUMMARY

The present disclosure provides an ion implantation apparatus and an ion implantation method which are capable of ion implantation in a short time and with a uniform concentration.

An embodiment of the inventive concept provides an ion implantation method including: providing a host material and a target into a chamber, the target including a first material; irradiating the target with a laser to generate an ion beam; and irradiating the host material with the ion beam to dope the host material with the first material, wherein while the host material is irradiated with the ion beam, the host material is rotated.

In an embodiment, the ion beam may have a propagation direction parallel to a first direction, and the host material may rotate around a rotation axis parallel to a second direction crossing the first direction.

In an embodiment, a distance between the host material and the target may be maintained while the host material rotates.

In an embodiment, the host material may include a portion having a cylindrical shape.

In an embodiment, the ion beam may include first particles and second particles having energy at least about 10 MeV higher than the first particles.

In an embodiment, the target may include: a first surface on which the laser is collimated; and a second surface facing the first surface, and the ion beam may propagate from the second surface in a direction away from the target.

In an embodiment, the ion implantation method may include irradiating a surface of the target with inert gas ions before irradiating the target with the laser.

In an embodiment, the target may further include a second material, wherein while the target may be irradiated with the laser, a position at which the laser is collimated may be changed to dope the host material with the first material and the second material.

In an embodiment of the inventive concept, an ion implantation method includes: providing a host material and a target into a chamber, the target including a first material; irradiating the target with a laser to generate an ion beam, the ion beam including first particles and second particles and the first particles having energy at least about 10 MeV higher than the second particles; and irradiating the host material with the ion beam to dope the host material with the first material.

In an embodiment, the number of particles having substantially the same energy as the first particles inside the ion beam may be smaller than the number of particles having substantially the same energy as the second particles.

In an embodiment, the Ion beam may further include third particles having smaller energy than the first particles and greater than the second particles, wherein the number of particles having substantially the same energy as the third particles may be greater than the number of particles having substantially the same energy as the first particles, and be smaller than the number of particles having substantially the same energy as the second particles.

In an embodiment, the ion beam may have a propagation direction parallel to a first direction, and while the host material is irradiated with the ion beam, the host material may rotate around a rotation axis parallel to a second direction crossing the first direction.

In an embodiment, the target may include: a first surface on which the laser is collimated; and a second surface facing the first surface, and the ion beam may propagate from the second surface in a direction away from the target.

In an embodiment, a distance between the host material and the target may be maintained while the host material rotates.

In embodiment of the inventive concept, an ion implantation apparatus includes: a chamber; a light source part configured to output a laser into a chamber; a target part configured to output an ion beam by receiving the laser; and a support part disposed inside the chamber and configured to support a host material so that the host material is irradiated with the ion beam, wherein the support part rotates the host material while the host material is irradiated with the ion beam.

In an embodiment, the support part may be configured to rotate the host material around a rotation axis in a direction perpendicular to a propagation direction of the ion beam.

In an embodiment, the ion implantation apparatus may further include an ion generator inside the chamber; and a gas supplier configured to supply an inert gas into the chamber.

In an embodiment, the ion implantation apparatus may further include a vacuum pump connected to the chamber.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIGS. 1 and 2 are views for explaining an ion implantation apparatuses according to embodiments of the inventive concept;

FIG. 3 is a flow chart for explaining a method for manufacturing an ion implantation apparatus according to embodiments of the inventive concept;

FIG. 4 is a view for explaining a method for manufacturing an ion implantation apparatus according to embodiments of the inventive concept and shows a target part and a cleaning part;

FIG. 5 is a view for explaining a method for manufacturing an ion implantation apparatus according to embodiments of the inventive concept and shows a target part and a host material;

FIGS. 6a and 6b are cross-sectional views corresponding to line A-A′ of FIG. 5 and illustrate a process in which ion particles are doped inside a host material;

FIGS. 7 and 8 are graphs illustrating the number of particles having the substantially same energy among the particles output from an ion implantation apparatus according to embodiments of the inventive concept; and

FIG. 9 is an enlarged cross-sectional view corresponding to line A-A′ of FIG. 5.

### DETAILED DESCRIPTION

Advantages and features of the present invention, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims. Like reference numerals refer to like elements throughout.

In the following description, the technical terms are used only for explaining a specific exemplary embodiment while not limiting the present invention. The terms of a singular form may include plural forms unless specifically mentioned. The meaning of ‘comprises’ and/or ‘comprising’ specifies a property, a region, a fixed number, a step, a process, an element and/or a component but does not exclude other properties, regions, fixed numbers, steps, processes, elements and/or components.

Additionally, the embodiment in the detailed description will be described with sectional views as ideal exemplary views of the present invention. In the figures, the dimensions of layers and regions are exaggerated for clarity of illustration. Accordingly, shapes of the exemplary views may be modified according to manufacturing techniques and/or allowable errors. Therefore, the embodiments of the present invention are not limited to the specific shape illustrated in the exemplary views, but may include other shapes that may be created according to manufacturing processes. For example, an etched region illustrated as a rectangle may have rounded or curved features. Areas exemplified in the drawings have general properties, and are used to illustrate a specific shape of a semiconductor package region. Thus, this should not be construed as limited to the scope of the present invention.

Hereinafter, ion implantation apparatuses according to embodiments of the inventive concept will be described in detail with reference to drawings.

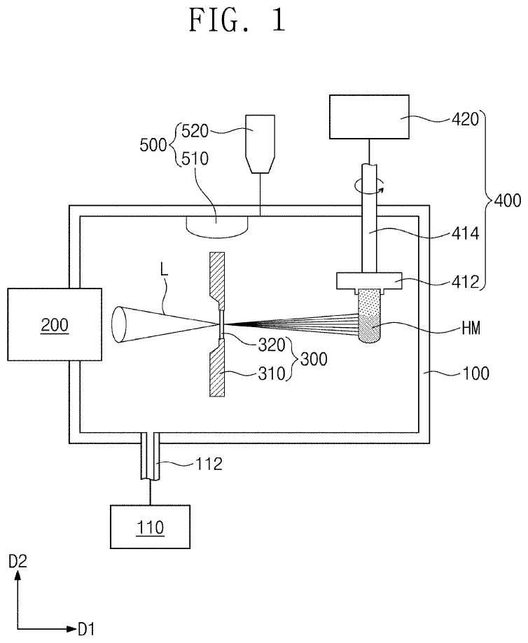

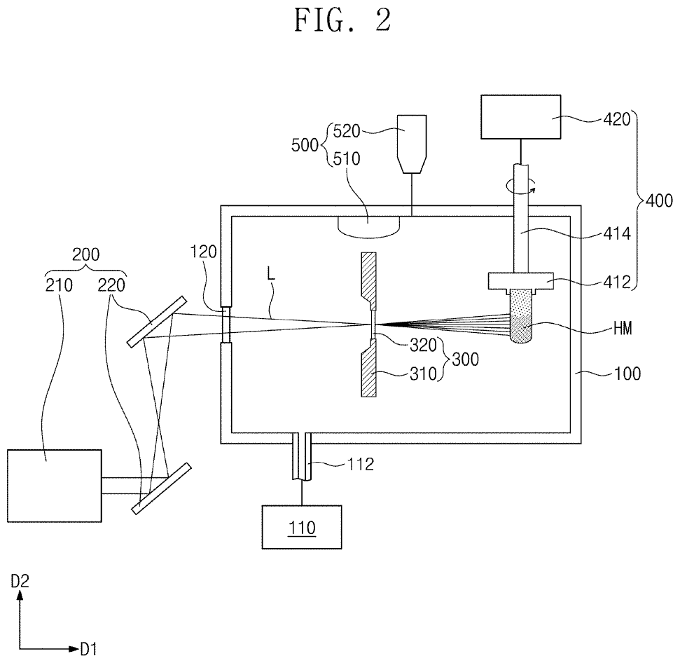

FIGS. 1 and 2 are views for explaining an ion implantation apparatuses according to embodiments of the inventive concept.

Referring to FIG. 1, an ion implantation apparatus according to embodiments of the inventive concept may include a chamber 100, a light source part 200, a target part 300, a support part 400, and a cleaning part 500.

The chamber 100 may have an internal space in which an ion implantation process is performed. The chamber 100 may be, for example, a vacuum chamber. An exhaust channel 112 may be provided in one side wall of the chamber 100. The exhaust channel 112 may be exhaust pipe for introducing air into the chamber 100 or discharging a gas inside the chamber 100 to the outside. A vacuum pump 110 may be connected to the exhaust channel 112. The vacuum pump 110 may include, for example, a turbo pump and/or a cryo-pump. The vacuum pump 110 may maintain the inside of the chamber 100 at a vacuum atmosphere while an ion implantation process is performed. The vacuum pump 110 may maintain the inside of the chamber 100 at a pressure within a range from about 1 Torr to about 1×10⁻¹¹ Torr

The light source part 200 may be provided on one side of the chamber 100. The light source part 200 may be configured to output a laser L into the chamber. For example, the light source part 200 may include a pico-second or femto-second laser device. For example, the light source part 200 may have a wavelength of about 700-900 nm and output a laser having a laser intensity of about 1×1020 W/cm² to about 1×1021 W/cm².

According to an embodiment, as illustrated in FIG. 1, a laser device of the light source part 200 may be connected to one side wall of the chamber 100 so that an output end thereof may be locates inside the chamber 100.

According to another example, as illustrated in FIG. 2, an output end of a laser device 210 may be located outside a chamber 100. The light source part 200 may be configured to provide the laser L into the chamber 100 through optical members 220 between the chamber 100 and the laser device 210. The optical members 220 may include, for example, a mirror and a collimator. Here, the chamber 100 may include a window 120 formed in one side wall thereof. The window 120 may be configured to receive the laser L into the chamber 100 from the outside of the chamber 100.

Referring again to FIG. 1, the target part 300 may be provided inside the chamber 100. The target part 300 may include a target holder 310 and a target 320. The target holder 310 may support the target 320 so that the laser L is focused on one surface of the target 320. For example, the target holder 310 may include a plurality of arms spaced apart from each other, and the target 320 may be interposed between the plurality of arms.

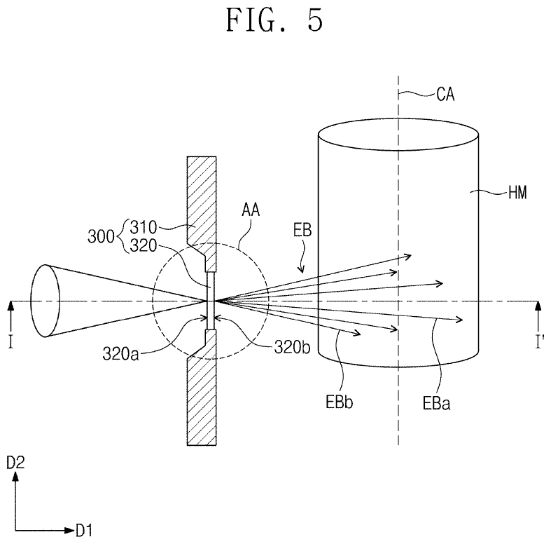

The target 320 may have a thin film shape. The target 320 may have a first surface and a second surface which face each other in a first direction D1, and either the first surface or the second surface may be supported by the target holder 310 so as to be perpendicular to the propagating direction of the laser L. The target 320 may generate an ion beam EB by receiving the laser L on one surface thereof. The process in which the target 320 receives the laser L to generate the ion beam EB will be described later with reference to FIG. 5. The target 320 may have a thickness of about 0.5-3 μm.

The target 320 may include any one among chromium (Cr), iron (Fe), titanium (Ti), neodymium (Nd), niobium (Nb), erbium (Er), ytterbium (Yb), cobalt (Co) and thulium (Tm). For example, when a host material HM includes ZnSe, the target 320 may include chromium (Cr) and/or iron (Fe). For example, when the host material HM includes Al₂O₃, the target 320 may include titanium (Ti) and/or niobium (Nb).

The cleaning part 500 may be provided on side of the chamber 100. The cleaning part 500 may be configured to perform a cleaning process with respect to the surface of the target 320 before irradiating the target 320 with the laser L. The cleaning part 500 may include: a gas supplier which supplies a cleaning gas into the chamber 100; and an ion generator 510 which generates ions using the cleaning gas. The cleaning part 500 may be, for example, an ion bombardment device. The gas supplier 520 may supply the cleaning gas into the chamber 100. The cleaning gas may be an inert gas. The inert gas may be, for example, argon (Ar). The ion generator 510 may generate ions using arc discharge or glow discharge. For example, when an argon gas is supplied into the chamber 100, the ion generator 510 may generate argon ions. The cleaning part 500 may generate ions and clean the surface of the target 320 using the generated ions.

The support part 400 which support the host material HM may be provided inside the chamber 100. The support part 400 may support the host material HM so that the host material HM may be irradiated with the ion beam EB generated from the target 320. The support part 400 may be configured so as to rotate the host material while the host material HM is irradiated with the ion beam EB.

According to an embodiment, the support part 400 may include: a stage 412 configured to support the host material HM; a driver 420 configured to rotate the stage 412; and a shaft 414 configured to connect the stage 412 and the driver 420. The stage 412 may support the host material HM while an ion implantation process is performed, and maintain the distance between the target 320 and the host material HM. For example, the stage 412 may include fingers which grip an upper portion (or a lower portion) of the host material HM. The driver 420 may control the rotation of the host material HM while the ion implantation process is performed. For example, the driver 420 may include a motor and a controller. The controller may receive information about the operation of the light source part 200 to operate the motor. The shaft 414 may provide the stage 412 with power generated from the driver 420. When the driver 420 is located outside the chamber 100, the shaft 414 may pass through a side wall of the chamber 100 from the stage 412 and extend to the outside of the chamber 100. Although not shown, a bellows may be provided for isolating the inside of the chamber 100 between the shaft 414 and the side wall of the chamber 100.

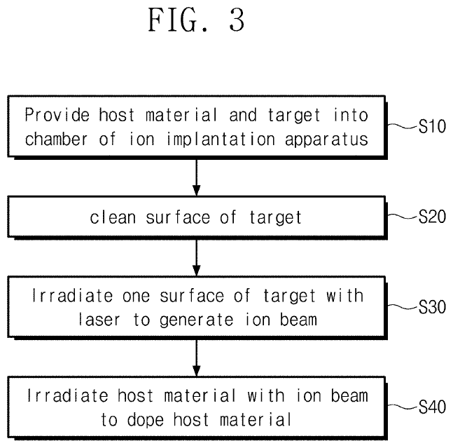

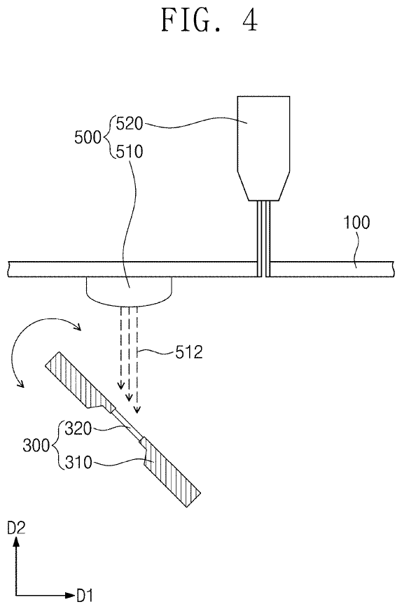

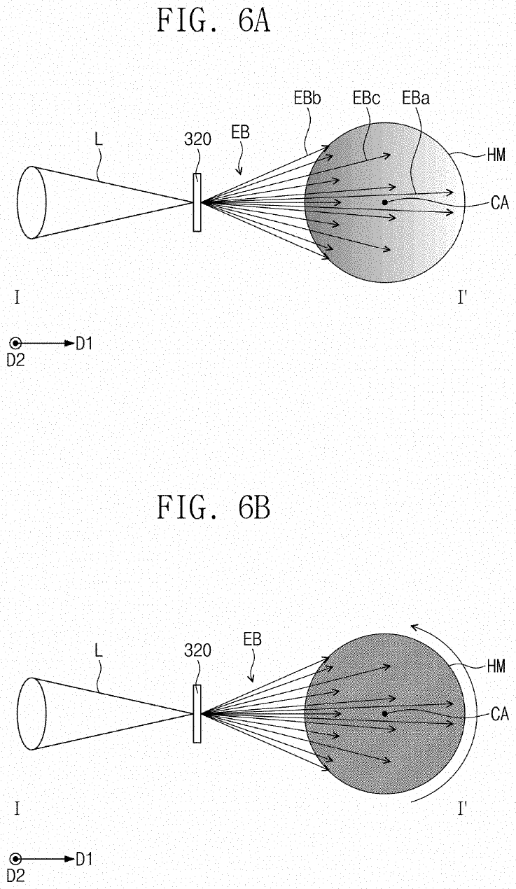

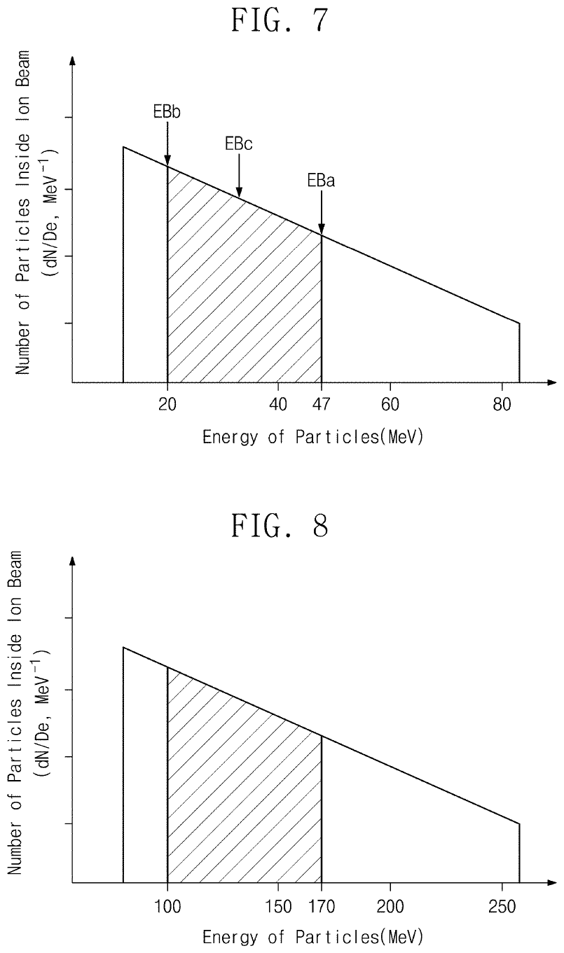

FIG. 3 is a flow chart for explaining a method for manufacturing ion implantation apparatus according to an embodiment of the inventive concept. FIG. 4 is a view for explaining a method for manufacturing an ion implantation apparatus according to an embodiment of the inventive concept and shows a target part and a cleaning part. FIG. 5 is a view for explaining a method for manufacturing an ion implantation apparatus according to embodiments of the inventive concept and shows a target part and a host material. FIGS. 6a and 6b are cross-sectional views corresponding to line A-A′ of FIG. 5 and illustrate a process in which ion particles are doped inside a host material. FIGS. 7 and 8 are graphs illustrating the number of particles having the substantially same energy among the particles output from an ion implantation apparatus according to embodiments of the inventive concept.

Referring to FIGS. 1 and 3, an ion implantation apparatus including a chamber 100, a light source part 200, a target holder 310, a support part 400, and a cleaning part 500 may be provided.

A host material HM and a target 320 may be provided inside the chamber 100 (S10). The host material HM is a target material for which an ion implantation process is performed, and may be a material for manufacturing an artificial jewel or a gain medium for light oscillation for a solid laser. The host material HM may include, for example, Al₂O₃ or ZnSe. The target 320 may include a first material for doping the host material HM. For example, the first material may include any one among chromium (Cr), iron (Fe), titanium (Ti), neodymium (Nd), niobium (Nb), erbium (Er), ytterbium (Yb), cobalt (Co) and thulium (Tm).

Referring to FIGS. 3 and 4, the surface of the target 320 may be cleaned (S20). An inert gas may be supplied into the chamber 100 from a gas supplier 520. The ion generator 510 may generate ions 512 from the inert gas supplied into the chamber 100 and discharge the ions to the surface of the target 320 fixed by the target holder 310. According to an embodiment, the ions 512 may be obliquely incident of both surfaces of the thin-film shaped target 320. As illustrated in FIG. 4, the target holder 310 may rotate so that the ions 512 may be incident on the two facing surfaces of the target 320. According to another embodiment, the ion generator 510 is moved and thus, the two surfaces of the target 320 may be irradiated with the ions 512. In addition, in still another embodiment, a plurality of ion generators 510 may also be provided inside the chamber 100 so that the two surfaces of the target 320 may be simultaneously irradiated with the ions 512.

Referring to FIGS. 3 and 5, an ion beam EB may be generated by irradiating a first surface 320a of the target 320 with a laser L. The ion beam EB may be output from a first surface 320a-facing second surface 320b of the target 320. The ion beam EB may have a predetermined diffusion angle and be output toward the host material HM. According to an embodiment, the ion beam EB may be output by means of a target normal sheath acceleration (TNSA) mechanism. Specifically, when the energy of the laser is accumulated on the first surface 320a of the target, electrons may pass through the target 320 in a high-temperature and high-speed state and form an electrostatic field on the second surface 320b due to Boltzmann distribution. At this point, most of the high-speed electrons are confined to the target 320 while forming Debye sheath due to coulomb potentials, and thus, a much stronger electrostatic field may be formed. The particles generated inside the target 320 may be accelerated in the direction away from the second surface 320b of the target 320 due to the electrostatic field. Second. The target 320 may have an appropriate thickness for generating a TNSA. For example, the target may have a thickness of about 0.5-3 μm.

Individual particles of the ion beam EB irradiated with the laser L may have a wide range energy distribution. Specifically, the particles (that is, individual ions inside the ion beam EB) discharged from the target 320 may have various energy, and the energy which each of the particles EB has may have, for example, a range of about 0.1-1,000 MeV. In addition, the particle EBa having the highest energy among the particles discharged from the target 320 may have energy which is at least about 10 MeV higher than that of the particle EB having the lowest energy. Thus, the particles EB doped inside the host material HM may be doped by mutually different depths.

Referring to FIGS. 3, 6a, and 6b, a host material HM is irradiated with an ion beam EB and may thereby be doped (S40). Since the ion beams EB discharged from the target 320 have various energy distributions, each of the particles EB may reach various depths of the host material HM. For example, the ion beam EB having low energy may be doped closed to a side surface adjacent to the target 320 in the host material. The ion beam EB having high energy may be doped at a far position from the target 320. Thus, the ion beams EB may de doped at various depths in the host material HM, and be doped with a relatively uniform concentration without an additional annealing process.

Referring to FIGS. 7 and 8 together, the number of ion beams EB having low energy may be greater than the number of ion beams EB having high energy. Thus, the closer to the target 320, the higher concentration the host material HM may be doped with.

For example, as illustrated in FIG. 7, energy which each of the particles inside the ion beam EB may have a range of about 10-83 MeV. The particles which have energy within a range of about 20-47 MeV among the particles inside the ion bean EB may be doped to the host material HM. The particles having energy smaller than about 20 MeV may not pass through the surface of the host material HM and may not be doped to the host material HM. The particles having energy greater than about 47 MeV may completely pass through the host material HM and may thus not be doped to the host material HM. At this point, the particles having the energy within a range of about 20-47 MeV may be doped to a portion close to the target 320, and the particles having high energy may be doped to a portion far from the target 320.

The energy of the particles doped to the host material HM may be different according to the types of the materials included in the host material HM and the shape of the host material HM. For example, as illustrated in FIG. 8, the particles doped to the host material HM may also have a range of about 100-170 MeV.

Referring to FIGS. 6a and 7, the number of particles per unit energy may have a linear distribution. The larger the energy, the smaller the number of particles per unit energy may be.

For example, the ion beam EB may include first particles EBa, second particles EBb, and third particles EBc. The first particles EBa may have energy which is at least about 10 MeV higher than the second particles EBb. The number of particles which have substantially the same energy as the first particles EBa may be greater than the number of particles having the substantially the same energy as the second particles EBb. In addition, the number of particles having substantially the same energy as the first third particles EBc may be greater than the number of particles having substantially the same energy as the first particles EBa, and be smaller than the particles having substantially the same energy as the second particles.

Referring again to FIGS. 3, 6a, and 6b, the host material HM may be rotated while being irradiated with the ion beam EB. The host material HM may be rotated by the support part 400 (see FIG. 1). The host material may be rotated around a rotation axis CA in a direction parallel to a second direction D2. That is, the host material may be rotated around a rotation axis CA in a direction perpendicular to the propagating direction of the laser L and the ion beam EB. Thus, the host material HM may be doped with more uniform concentration.

According to embodiments of the inventive concept, the particles inside the ion beam EB discharged by the laser (L) may have a wide range of energy distribution. Accordingly, an ion implantation apparatus and an ion implantation method may be provided which are capable of ion implantation to a host material HM with a uniform concentration and without additional heat treatment.

In addition, according to embodiments of the inventive concept, while an ion implantation process is performed, the host material HM may be rotated, and thus, the uniformity of the dopant concentration inside the doped host material may be improved.

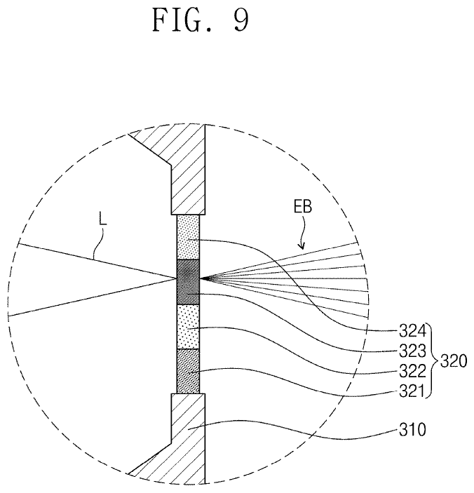

FIG. 9 is an enlarged cross-sectional view corresponding to line A-A′ of FIG. 5.

Referring to FIG. 9, the target 320 may include first to fourth portions 321, 322, 323 and 324. Each of the first to fourth portions 321, 322, 323 and 324 may include any one among chromium (Cr), iron (Fe), titanium (Ti), neodymium (Nd), niobium (Nb), erbium (Er), ytterbium (Yb), cobalt (Co) and thulium (Tm), and may include materials different from each other. For example, the first portion 321, the second portion 322, the third portion 323 and the fourth portion 324 may respectively include chromium (Cr), neodymium (Nd), titanium (Ti), and ytterbium (Yb). Referring to FIGS. 3 and 5 together, while the ion beam EB is generated, the position at which the laser is collected on the first surface 320a of the target 320 may become different. Thus, the ion beams EB including various ions may be generated, and the host material HM may be doped with various materials.

According to embodiments of the inventive concept, particles discharged by the laser inside the ion beam may have wide range of energy distribution. Thus, an ion implantation apparatus and an ion implantation method may be provided which are capable of ion implantation to a host material HM with a uniform concentration and without additional heat treatment.

In addition, according to embodiments of the inventive concept, while an ion implantation process is performed, the host material HM may be rotated, and thus, the uniformity of the dopant concentration inside the doped host material may be improved.

In addition, according to embodiments of the inventive concept, the time required for ion implantation may be reduced.

The above-disclosed subject matter is to be considered illustrative and not restrictive, and the appended claims are intended to cover all such modifications, enhancements, and other embodiments, which fall within the true spirit and scope of the inventive concept. Thus, to the maximum extent allowed by law, the scope of the inventive concept is to be determined by the broadest permissible interpretation of the following claims and their equivalents, and shall not be restricted or limited by the foregoing detailed description. Thus, the above-disclosed embodiments are to be considered illustrative and not restrictive.

What is claimed is:

1. An ion implantation method comprising:
providing a host material and a target into a chamber, the target comprising a first material;
irradiating the target with a laser to generate an ion beam; and
irradiating the host material with the ion beam to dope the host material with the first material, wherein
while the host material is irradiated with the ion beam, the host material is rotated.

2. The ion implantation method of claim 1, wherein the ion beam comprises first particles and second particles having energy at least about 10 MeV higher than the first particles.

3. The ion implantation method of claim 1, wherein
the ion beam has a propagation direction parallel to a first direction, and
the host material rotates around a rotation axis parallel to a second direction crossing the first direction.

4. The ion implantation method of claim 1, wherein a distance between the host material and the target is maintained while the host material rotates.

5. The ion implantation method of claim 1, wherein the host material comprises a portion having a cylindrical shape.

6. The ion implantation method of claim 1, wherein the target comprises:
a first surface on which the laser is collimated; and
a second surface facing the first surface, and
the ion beam propagates from the second surface in a direction away from the target.

7. The ion implantation method of claim 1, comprising irradiating a surface of the target with inert gas ions before irradiating the target with the laser.

8. The ion implantation method of claim 1, wherein
the target further comprises a second material, and
while the target is irradiated with the laser, a position at which the laser is collimated is changed to dope the host material with the first material and the second material.

9. An ion implantation method comprising:
providing a host material and a target into a chamber, the target comprising a first material;
irradiating the target with a laser to generate an ion beam, the ion beam comprising first particles and second particles and the first particles having energy at least about 10 MeV higher than the second particles; and
irradiating the host material with the ion beam to dope the host material with the first material.

10. The ion implantation method of claim 9, wherein the number of particles having substantially the same energy as the first particles inside the ion beam is smaller than the number of particles having substantially the same energy as the second particles.

11. The ion implantation method of claim 9, wherein the ion beam further comprises third particles having smaller energy than the first particles and greater than the second particles,
wherein the number of particles having substantially the same energy as the third particles is greater than the number of particles having substantially the same energy as the first particles, and is smaller than the number of particles having substantially the same energy as the second particles.

12. The ion implantation method of claim 9, wherein the ion beam has a propagation direction parallel to a first direction, and while the host material is irradiated with the ion beam, the host material rotates around a rotation axis parallel to a second direction crossing the first direction.

13. The ion implantation method of claim 9, wherein the target comprises:
a first surface on which the laser is collimated; and
a second surface facing the first surface, and the ion beam propagates from the second surface in a direction away from the target.

14. The ion implantation method of claim 13, wherein a distance between the host material and the target is maintained while the host material rotates.

15. An ion implantation apparatus comprising:
a chamber;
a light source part configured to output a laser into a chamber;
a target part configured to output an ion beam by receiving the laser; and
a support part disposed inside the chamber and configured to support a host material so that the host material is irradiated with the ion beam, wherein
the support part rotates the host material while the host material is irradiated with the ion beam.

16. The ion implantation apparatus of claim 15, wherein the support part is configured to rotate the host material around a rotation axis in a direction perpendicular to a propagation direction of the ion beam.

17. The ion implantation apparatus of claim 15, further comprising: an ion generator inside the chamber; and a gas supplier configured to supply an inert gas into the chamber.

18. The ion implantation apparatus of claim 15, further comprising a vacuum pump connected to the chamber.
